(19) United States
(12) Patent Application Publication
(10) Pub. No.: US 2026/0040955 A1
(43) Pub. Date: Feb. 5, 2026

(54) PACKAGE MANUFACTURABLE USING THERMOPLASTIC STRUCTURE COVERING A COMPONENT ASSEMBLY SECTION WITHOUT COVERING A LEAD SECTION

(71) Applicant: Infineon Technologies AG, Neubiberg (DE)

(72) Inventors: Chee Keong KUAN, Melaka (MY); Syahir ABD HAMID, Melaka (MY)

(73) Assignee: Infineon Technologies AG, Neubiberg (DE)

(21) Appl. No.: 19/269,861

(22) Filed: Jul. 15, 2025

(30) Foreign Application Priority Data
Aug. 2, 2024 (DE) 10 2024 122 201.8

(51) Int. Cl. H01L 21/48; H01L 23/00; H01L 23/367; H01L 23/495

(52) U.S. Cl. CPC H01L 21/4839; H01L 21/4875; H01L 23/3677; H01L 23/49551; H01L 23/49582; H01L 23/49503; H01L 24/40; H01L 24/48; H01L 24/73; H01L 2224/40245; H01L 2224/48245; H01L 2224/48472; H01L 2224/73271

(57) ABSTRACT

A package and method is disclosed. In one example, the package comprises a component assembly section, at least one electronic component being assembled with the component assembly section, at least one lead section being electrically coupled with the at least one electronic component and/or with the component assembly section, an encapsulant at least partially encapsulating the at least one electronic component and partially encapsulating the component assembly section and the at least one lead section so that part of the component assembly section and part of the at least one lead section are exposed beyond the encapsulant. A thermoplastic structure covers an exposed area of the component assembly section without covering an exposed area of the at least one lead section.

### CROSS-REFERENCE TO RELATED APPLICATION

This Utility Patent application claims priority to German Patent Application No. 10 2024 122 201.8 filed Aug. 2, 2024, which is incorporated herein by reference.

### BACKGROUND

### Technical Field

Various embodiments relate generally to packages and a method of manufacturing a package.

### Description of the Related Art

Packages may be denoted as encapsulated electronic components with electrical connections extending out of the encapsulant and being mountable on an electronic periphery, for instance on a printed circuit board.

Packaging cost is an important driver for the industry. Related with this are performance, dimensions and reliability. The different packaging solutions are manifold and have to address the needs of the application.

### SUMMARY

There may be a need for a package with high reliability.

According to an exemplary embodiment, a package is provided which comprises a component assembly section, at least one electronic component being assembled with the component assembly section, at least one lead section being electrically coupled with the at least one electronic component and/or with the component assembly section, an encapsulant at least partially encapsulating the at least one electronic component and partially encapsulating the component assembly section and the at least one lead section so that part of the component assembly section and part of the at least one lead section are exposed beyond the encapsulant, and a thermoplastic structure covering an exposed area of the component assembly section without covering an exposed area of the at least one lead section.

According to another exemplary embodiment, a package is provided which comprises a component assembly section plated with a first metallic plating structure of a first plating material, at least one electronic component being assembled with the component assembly section, at least one lead section plated with the first metallic plating structure of the first plating material and being electrically coupled with the at least one electronic component and/or with the component assembly section, an encapsulant at least partially encapsulating the at least one electronic component and partially encapsulating the component assembly section and the at least one lead section so that part of the component assembly section and part of the at least one lead section are exposed beyond the encapsulant, and a second metallic plating structure of a second plating material plating an exposed area of the at least one lead section on top of the first metallic plating structure of the first plating material, wherein an exposed area of the component assembly section is not plated with said second plating material.

According to still another exemplary embodiment, a method of manufacturing a package is provided, wherein the method comprises assembling at least one electronic component with a component assembly section, electrically coupling at least one lead section with the at least one electronic component and/or with the component assembly section, at least partially encapsulating the at least one electronic component and partially encapsulating the component assembly section and the at least one lead section with an encapsulant so that part of the component assembly section and part of the at least one lead section are exposed beyond the encapsulant, and forming a thermoplastic structure covering an exposed area of the component assembly section without covering an exposed area of the at least one lead section.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 to FIG. 5 show cross-sectional views of structures obtained during carrying out a method of manufacturing a package, shown in FIGS. 3-5, according to an exemplary embodiment.

FIG. 6 illustrates a flowchart of a method of manufacturing a package according to an exemplary embodiment.

FIG. 7 illustrates a flowchart of a method of manufacturing a package according to another exemplary embodiment.

FIG. 8 illustrates a flowchart of a method of manufacturing a package according to still another exemplary embodiment.

FIG. 9 illustrates a side view of a package according to an exemplary embodiment.

FIG. 10 illustrates a side view of a package according to another exemplary embodiment.

FIG. 11 to FIG. 13 show plan views of structures obtained during carrying out a method of manufacturing a package according to an exemplary embodiment.

FIG. 14 shows a cross-sectional view of a package according to another exemplary embodiment.

### DETAILED DESCRIPTION

According to an exemplary embodiment, a package is provided which comprises a component assembly section, at least one electronic component being assembled with the component assembly section, at least one lead section being electrically coupled with the at least one electronic component and/or with the component assembly section, an encapsulant at least partially encapsulating the at least one electronic component and partially encapsulating the component assembly section and the at least one lead section so that part of the component assembly section and part of the at least one lead section are exposed beyond the encapsulant, and a thermoplastic structure covering an exposed area of the component assembly section without covering an exposed area of the at least one lead section.

According to another exemplary embodiment, a package is provided which comprises a component assembly section plated with a first metallic plating structure of a first plating material, at least one electronic component being assembled with the component assembly section, at least one lead section plated with the first metallic plating structure of the first plating material and being electrically coupled with the at least one electronic component and/or with the component assembly section, an encapsulant at least partially encapsulating the at least one electronic component and partially encapsulating the component assembly section and the at least one lead section so that part of the component assembly section and part of the at least one lead section are exposed beyond the encapsulant, and a second metallic plating structure of a second plating material plating an exposed area of the at least one lead section on top of the first metallic plating structure of the first plating material, wherein an exposed area of the component assembly section is not plated with said second plating material.

According to still another exemplary embodiment, a method of manufacturing a package is provided, wherein the method comprises assembling at least one electronic component with a component assembly section, electrically coupling at least one lead section with the at least one electronic component and/or with the component assembly section, at least partially encapsulating the at least one electronic component and partially encapsulating the component assembly section and the at least one lead section with an encapsulant so that part of the component assembly section and part of the at least one lead section are exposed beyond the encapsulant, and forming a thermoplastic structure covering an exposed area of the component assembly section without covering an exposed area of the at least one lead section.

According to an exemplary embodiment, a package may be equipped with a component assembly section (such as a die pad) on which one or more electronic components (for example a semiconductor chip, for instance a power semiconductor chip) may be mounted. One or more lead sections (which may comprise one or more leads being accessible from an exterior of the package for establishing an electric connection between an interior of the package and an electronic periphery) of the package may be electrically connected with said electronic component and/or with said component assembly section. The electronic component, the component assembly section and the lead section may be encapsulated by an encapsulant (such as a mold compound). However, the component assembly section and the lead section may be partially exposed beyond the encapsulant, i.e. a portion thereof may be free of a coverage by said encapsulant. Advantageously, a thermoplastic structure may cover selectively an encapsulant-exposed area of the component assembly section, but will not cover the encapsulant-exposed area of the lead section. Beneficially, this may allow to selectively plate the exposed lead section while the exposed component assembly section may be prevented from being plated. At the same time, the surface of the component assembly section may be protected against undesired impact from an environment (such as oxidation, dust and/or moisture) as long as the component assembly section remains covered with the thermoplastic structure. When desired (for instance during assembly of the package with a mounting base and/or a heat sink), the thermoplastic structure may be simply removed from the component assembly section, for instance by peeling it off. Advantageously, the thermoplastic structure does not need curing and may provide excellent resistance to plating, in particular tin plating. Consequently, an undesired non-uniform plating on a component assembly section may be reliably prevented by the thermoplastic structure. Descriptively speaking, the thermoplastic structure may act as a mask for selective plating. This may keep the component assembly section sufficiently smooth for a thermally advantageous assembly, for instance for mounting a heat sink or the like, without an excessive increase of the thermal resistance at a surface of the component assembly section.

According to an exemplary embodiment, the thermoplastic structure may be removed from the component assembly section after selective plating on an exposed surface portion of the lead section. In such a scenario, it may be advantageous to have a first metallic plating structure of a first plating material (such as NiNiP) on a pre-fabricated carrier comprising component assembly section as well as lead section and selectively a second metallic plating structure of a second plating material (for instance tin) only on the lead section but not on the component assembly section. This configuration may be obtained due to the fact that the latter may be reliably prevented from additional plating by a temporary thermoplastic structure.

### Description of Further Exemplary Embodiments

In the following, further exemplary embodiments of the packages and the method will be explained.

In the context of the present application, the term “package” may particularly denote an electronic device which may comprise one or more electronic components mounted on a carrier. Said constituents of the package may be encapsulated at least partially by an encapsulant. Optionally, one or more electrically conductive interconnect bodies (such as bond wires and/or clips) may be implemented in a package, for instance for electrically coupling the electronic component with the carrier and/or with leads.

In the context of the present application, the term “carrier” may particularly denote a support structure (which may be at least partially electrically conductive) which serves as a mechanical support for the one or more electronic components to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may comprise a die pad. In particular, a carrier may comprise at least a component assembly section and a lead section.

In the context of the present application, the term “component assembly section” may particularly denote a section of the carrier which is configured for mounting at least one electronic component thereon. For instance, the component assembly section may be a die pad. It may also be possible that the component assembly section is a clip. In an embodiment, the component assembly section may be a planar or bent plate-like metallic body or region.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), a light emitting, semiconductor-based device (such as a light emitting diode (LED) or LASER), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated. Semiconductor chips implemented according to exemplary embodiments may be formed in silicon technology, gallium nitride technology, silicon carbide technology, etc.

In the context of the present application, the term “lead section” may particularly denote an electrically conductive (for instance strip shaped) element (which may be planar or bent) which may be assigned functionally to the component assembly section and which serves for contacting the electronic component with an exterior of the package. For instance, a lead section may be partially encapsulated and partially exposed with respect to an encapsulant. When the carrier forms part of a leadframe, leads or lead sections may surround a die pad of the carrier, for instance at two opposing sides or at all four sides. The one or more lead sections may or may not form part of the carrier.

In the context of the present application, the term “encapsulant” may particularly denote a substantially electrically insulating material surrounding at least part of an electronic component and part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity.

In the context of the present application, the term “thermoplastic structure” may particularly denote a physical body such as a sheet or layer made of a plastic polymer material that becomes pliable at an elevated temperature and solidifies upon cooling. With increased temperature, a thermoplastic structure may yield a viscous liquid or a flowable medium, wherein the thermoplastic structure may be reshaped in this state. Thermoplastics may be denoted as plastics that can be deformed in a certain temperature range. This process may be reversible, which means that it can be repeatedly brought to a molten or flowable state by reheating. For instance, the thermoplastic structure may be reversibly deformable by temperature increase. An example for a thermoplastic structure is a structure made of hot melt adhesive. For example, the thermoplastic structure may be a thermoplastic layer. The thermoplastic layer may be coated in a non-conformal way and may thus be flexibly used in an area where it is desired.

In the context of the present application, the term “metallic plating structure of a plating material” may particularly denote a layer or another structure formed at least partially by plating, for example by depositing a metallic material on a surface (for instance by electroless plating or sputtering). It is possible to do plating directly on a lead section, a component assembly section or an entire carrier. A sputtering mask, for instance in form of a thermoplastic structure, may be used to define a plated region. A metallic plating structure may function as wettability layer having a surface property promoting wetting by a (for example flowable during processing) connection medium (such as solder or adhesive) thereon. In particular, wetting may denote the ability of a connection medium to maintain contact with a solid surface of the wettability layer, in particular resulting from intermolecular interactions when the two are brought together. The degree of wetting may be denoted as wettability and may be determined by a force balance between adhesive and cohesive forces.

In an embodiment, the thermoplastic structure is made of a material being reversibly deformable, for example being bringable in a flowable state, by heating. For instance, a thermoplastic material of the thermoplastic structure may be repeatedly converted between a solid and a flowable state. Such a thermoplastic structure does not require curing (in particular UV curing may be dispensable) and is therefore highly appropriate as plating mask applicable in a simple manufacturing process.

In an embodiment, the exposed area of the at least one lead section is plated with a metallic plating structure of a plating material, and the exposed area of the component assembly section is not plated with said plating material. This may be accomplished by covering the exposed area of the component assembly section with a thermoplastic structure during plating the exposed portion of the lead section. For instance, said metallic plating structure may comprise or consist of tin.

In an embodiment, the thermoplastic structure is made of a plating resistant material, for example a tin plating resistant material. Thus, no or at least no excessive amount of plating material will be deposited on the thermoplastic structure (and on the component assembly section thereunder) during plating the lead section.

In an embodiment, the thermoplastic structure is made of a material being temperature resistant, for example at least up to 140° C., preferably at least up to 155° C. Advantageously, the material of the thermoplastic structure may be configured for withstanding a thermal annealing process which may be carried out during manufacturing the package. Preferably, the material of the thermoplastic structure may withstand conditions of 155° C. for at least 120 minutes.

In an embodiment, the thermoplastic structure comprises an adhesive, for example a hot melt adhesive (HMA). For instance, the hot melt adhesive may be a polyolefin-based hot melt adhesive, optionally also comprising an acrylic adhesive. Other materials are however possible. When the thermoplastic structure is adhesive, it may reliably remain on the exposed surface of the component assembly section to prevent plating thereon. Highly preferable is a hot melt adhesive as thermoplastic structure. The term “hot melt adhesive” or hot glue may denote a thermoplastic adhesive which may be applied on the component assembly section in a molten state before solidifying as a thermoplastic layer. For example, a hot melt adhesive may be applied by a hot melt dispensing machine, by a hot glue gun, by dipping or spraying. Advantageously, the application of a hot melt adhesive neither requires drying nor curing. For example, a hot melt adhesive may comprise at least one polymer as base material and various additives for fine-tuning its properties.

In an embodiment, the thermoplastic structure is a continuous layer. Thus, the thermoplastic structure may cover the entire exposed surface area of the component assembly section in an uninterrupted way without gaps. This may ensure that the entire exposed surface area of the exposed pad-type component assembly section may be protected against undesired plating as well as against environmental influences.

In an embodiment, the thermoplastic structure is configured for being removed from the exposed area of the component assembly section by peeling off the thermoplastic structure. For the peel off process, there is preferably no need to heat or soft the thermoplastic material. It may be possible to simply use a mechanical force to peel it off, for example by hands, by a machine or by tape to tape it off.

In an embodiment, the package comprises a metallic plating structure covering the exposed area of the at least one lead section. Said metallic plating structure of a certain plating metal (for instance comprising tin) may be absent at the exposed surface of the component assembly section thanks to the protecting function of the thermoplastic structure thereon.

However, it may be possible that another metallic plating structure of another plating metal (such as NiNiP, i.e. Nickel/Nickel Phosphorus) is present both on a surface of the component assembly section as well as on a surface of the lead section. For instance, it is possible that a carrier (such as a leadframe) is plated with said other metallic plating structure of said other plating metal (such as NiNiP), for example during carrier fabrication. Said carrier may comprise the component assembly section and said lead section. When later in the manufacturing process an exposed portion of the component assembly section is covered by a thermoplastic structure while the exposed lead section is not covered by such a thermoplastic structure, the execution of a further plating process will form, on part of the lead section but not on the component assembly section, a double-layer of a bottom-sided metallic plating structure (such as NiNiP) covered by a top-sided other metallic plating structure (such as tin). Hence, the component assembly section can be made of a single-plated metal body, for example may be made of a metal body with a NiNiP plating. The lead section can be made of a double-plated metal body, for example may be made of a metal body with a NiNiP plating and a tin plating partially thereon.

In other embodiments, the carrier comprising component assembly section and lead section may be non-plated (for instance may be a pure copper leadframe structure), so that the execution of a plating process will form a single plating structure (such as tin) on the exposed lead section while the component assembly section covered by the thermoplastic structure is not plated at all (for instance remains pure copper). Thus, the component assembly section may be made of a non-plated metal body, for example may be made of copper.

In an embodiment, the component assembly section comprises a die pad and/or a clip. A “die pad” may denote a portion of a carrier dedicated for assembling an electronic component, such as a semiconductor chip, thereon, for instance by soldering, sintering or adhesive glue. In the context of the present application, the term “clip” may particularly denote a three-dimensionally curved connection element which comprises an electrically conductive material such as copper and is an integral body with sections to be connected to chip terminals and/or a chip carrier and/or leads.

In an embodiment, the component assembly section and/or the at least one lead section forms or form part of a structured and/or bent metallic plate (for example comprising copper and/or aluminum), for instance of a leadframe structure. In the context of the present application, the term “leadframe” may particularly denote a sheet-like metallic structure which can be bent, punched and/or patterned so as to form leadframe bodies as mounting sections for mounting chips, and connection leads for electric connection of the package to an electronic environment. In an embodiment, the leadframe may be a metal plate (in particular made of copper) which may be patterned, for instance by stamping or etching. Forming a chip carrier as a leadframe is a cost-efficient and mechanically as well as electrically highly advantageous configuration in which a low ohmic connection of chips can be combined with a robust support capability of the leadframe. Furthermore, a leadframe may contribute to the thermal conductivity of the package and may remove heat generated during operation of the chip(s) as a result of the high thermal conductivity of the metallic (in particular copper) material of the leadframe.

In an embodiment, the method comprises removing the thermoplastic structure to thereby expose the component assembly section. For example, the thermoplastic structure may function as a temporary protection foil protecting the exposed component assembly section against plating and against environmental influences (such as a corrosive or oxidative atmosphere, etc.).

In an embodiment, the method comprises mounting a heat sink on the exposed component assembly section, for example by a solder structure or using a thermal interface structure. In the context of the present application, the term “heat sink” may in particular denote a highly thermally conductive body which may be thermally coupled with the exposed component assembly section of the package for removing heat generated by the electronic component(s) during operation of the package. For example, the heat sink may be made of a material having a thermal conductivity of at least 10 W/mK, in particular at least 50 W/mK, even up to 200 W/mK or even above. For instance, the heat sink may be made of an electrically conductive material such as copper, an alloy of copper and/or aluminium, but may also comprise a ceramic material. The heat sink may be directly or indirectly thermally coupled with the component assembly section, for instance by a solder. For example, the heat sink may comprise a thermally conductive body (such as a metal plate) with a plurality of cooling fins extending from the thermally conductive body. Additionally or alternatively, liquid and/or gas cooling may be accomplished by a heat sink as well. The thermal coupling of the package with a heat sink may ensure an efficient cooling. For promoting transition of heat through the exposed component assembly section of the package, a heat sink can be added. Doing this using an electrically insulating TIM (thermal interface material) is an option. However, soldering the heat sink to the exposed component assembly section may enable an excellent thermal conduction.

In an embodiment, the method comprises mounting a decoupling structure on the exposed component assembly section. For example, a decoupling structure may be mounted which comprises a central thermally conductive and electrically insulating sheet (for example made of a ceramic) covered with a respective metallic layer (such as a metal foil, for instance made of copper or aluminum) on each of two opposing main surfaces thereof so that one of said metallic layers is connected with the exposed component assembly section and the other one of said metallic layers is exposed towards an exterior. For example, the decoupling structure may be a Direct Copper Bonding (DCB) substrate or a Direct Aluminum Bonding (DAB) substrate. Advantageously, the central thermally conductive and electrically insulating sheet may thermally couple an interior of the package with the exterior metallic layer of the decoupling structure. This may ensure a proper removal of heat generated during operation of the package, in particular by the at least one encapsulated electronic component. At the same time, said sheet may electrically decouple an interior of the package with respect to an exterior thereof in order to achieve electric reliability and safety during operation. The inner metallic layer may allow to connect the decoupling structure with the exposed component assembly section. The exterior metallic layer may provide the possibility to connect the package with a thermal or electrical environment, for instance a heat sink or a mounting base such as a printed circuit board.

In an embodiment, the method comprises plating the exposed area of the at least one lead section with a metallic plating structure while the thermoplastic structure protects the component assembly section against metallic plating. After having functioned as plating mask, the thermoplastic structure may or may not be removed from the package.

In an embodiment, the method comprises removing the thermoplastic structure after said plating. After exposure of the component assembly section due to the removal of the thermoplastic structure, a solder connection or the like may be established between the component assembly section and another component such as a heat sink.

In an embodiment, the method comprises, before forming the thermoplastic structure, removing surface oxide at least from said exposed area of the component assembly section exposed beyond the encapsulant. Thus, a surface oxide removal process (for example copper descaling) may be carried out prior to hot melt adhesive masking. This may ensure a low thermal resistance of the component assembly structure.

In an embodiment, the method comprises forming the thermoplastic structure by dispensing flowable thermoplastic structure material using a dispensing machine, and subsequently solidifying said thermoplastic structure material by a temperature reduction to thereby obtain the thermoplastic structure. By taking this measure, the thermoplastic structure may be applied onto the component assembly section a simple way, in particular without curing.

In an embodiment, the first plating material comprises NiNiP. In an embodiment, the second plating material comprises tin. This may lead, on the component assembly section, to a single plating structure made of NiNiP. On the lead section or part thereof, this may lead to a plating double-layer comprising a bottom-sided NiNiP layer and a tin layer on top thereof. However, other plating materials and plating material combinations are possible.

In an embodiment, the package is configured as power module, for instance molded power module such as a semiconductor power package. For instance, an exemplary embodiment of the package may be an intelligent power module (IPM). Another exemplary embodiment of the package is a dual inline package (DIP).

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts (in particular fully compatible with standard TO packaging concepts) and appears externally as a conventional package, which is highly user convenient.

In an embodiment, the electronic component is a semiconductor power chip. Thus, the semiconductor component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, the package comprises a plurality of electronic components, in particular semiconductor components, encapsulated by the package encapsulant. Thus, the package may comprise one or more semiconductor components (for instance at least one passive component, such as a capacitor, and at least one active component).

As substrate or wafer forming the basis of the electronic component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

A conventional top side cooled package (for example a QDPAK-type package or a TOLT (TO-Leaded top-side cooling)-type package) may result, after a reflow process, in a tin non-uniformity on an exposed metal surface. This poses challenges for assembly of the package, as a smooth metal surface may be desired for mounting a heat sink or for providing an exposed pad metal in order to achieve a high heat dissipation performance.

In another conventional approach, a tin-free exposed pad metal in a TOLT package may be achieved by using tape masking for supporting a selective plating process. However, this approach may have the drawback that such a copper exposed pad package may suffer from the fact that copper can be easily be oxidized. Since an oxidized copper surface may increase the thermal resistance, this artifact may lower the heat dissipation performance. In addition, conventional tape masking may require an ultraviolet (UV) curing process, which increases the manufacturing effort.

According to an exemplary embodiment, a package (such as a power semiconductor package) may comprise a component assembly section (like a die paddle) carrying at least one electronic component (such as a semiconductor die). A lead section may have one or more leads for contacting the electronic component from an exterior of the package. An encapsulant (for example an epoxy mold compound) may encapsulate not only the electronic component(s) but also part of component assembly section and lead section. Beneficially, a (in particular temporary) thermoplastic structure may be placed selectively on the component assembly section where being exposed with respect to the encapsulant. Further advantageously, said thermoplastic structure may be prevented from covering the exposed lead section surface. By taking this measure, a plating (or an additional plating) only of the exposed lead section without plating (or without additionally plating) the component assembly section may be ensured. The thermoplastic structure may also function as a protection structure for protecting the component assembly section against undesired environmental influences (like oxidative conditions, dirt and/or humidity). After selectively plating the lead section or directly before assembling the package with a mounting base (such as a printed circuit board) and/or a heat sink (for instance a cooling plate with fins), the thermoplastic structure may be detached from the component assembly section. In terms of keeping the manufacturing effort reasonably low, it is advantageous that the thermoplastic structure does not require curing (such as ultraviolet curing). By shielding the component assembly section against plating during plating of the lead section, the exterior surface of the component assembly section may remain smooth to thereby keep the thermal resistance small and/or to simplify assembly of the package for forming an electronic device.

Hence, a thermoplastic structure may be used for increasing thermal performance of a top side cooling-type package. By protecting an exposed component assembly section against plating, the thermoplastic structure may avoid an undesired irregular surface of the component assembly section. This may ensure a high thermal performance. At the same time, the thermoplastic structure may suppress oxidation of a metallic surface of the component assembly section, for instance a copper surface, which may also contribute to a high thermal performance.

For applying the thermoplastic structure to an exposed component assembly section, it may be possible to melt a resin-based hot melt adhesive to render it liquid, for instance by a temperature increase to 150° C. to 180° C. In this liquid or flowable state, the hot melt adhesive (or another appropriate thermoplastic structure) may be dispensed on the component assembly section (which may be a die pad). The hot melt adhesive may then solidify (for instance due to a temperature decrease) without the need of curing. Thereafter, the solidified thermoplastic structure may properly function as plating resistance.

In a preferred embodiment, the thermoplastic structure may be peeled off from the component assembly section after selective plating of the lead section, for example before completing manufacture of the package. Beneficially, a first metallic plating structure of a first plating material (like NiNiP) may be pre-formed on component assembly section and lead section, and a second metallic plating structure of a second plating material (like tin) may be plated selectively on the lead section only, while the thermoplastic-protected component assembly section remains free of said second metallic plating structure.

In particular, an exemplary embodiment provides a peelable mask in form of the thermoplastic structure for selective plating. The peelable property of the thermoplastic structure may support its easy removal. The use of a thermoplastic structure as a plating mask may keep the manufacturing effort moderate, since UV curing may be dispensable.

Preferably, said thermoplastic structure may be embodied as a holt melt adhesive (HMA). Advantageously, a thermoplastic structure may solidify instantly upon cooling, hence no curing is required. A thermoplastic structure may also have a reliable resistance to tin plating chemicals. Moreover, a thermoplastic structure may have a high resistance to annealing conditions. Further advantageously, a thermoplastic structure may be peelable without residues.

Advantageously, exemplary embodiments may provide a top side cooling-type package with tin-free exposed pad for manufacturing a (for instance copper-based) exposed pad package. A tin-free component assembly section (constituting said exposed pad) may also allow to mount a DCB (Direct Copper Bonding)-type carrier on the exposed component assembly section.

Exemplary embodiments may provide a simple manufacturing process reducing the number of process stages in comparison with conventional approaches. Moreover, the package manufacturing effort may be reduced, as no curing process may be required for the thermoplastic structure. Advantageously, a peelable mask in form of the thermoplastic structure may remain on the package as protective layer on the component assembly section or exposed pad. Optionally, said thermoplastic structure may be removed before assembly of the package to an electronic and/or a thermal environment.

In particular, an exemplary embodiment may apply a layer of thermoplastic material with high thermal resistance properties onto a metal exposed surface (for example NiNiP or copper) in form of a component assembly section of the package. Advantageously, the thermoplastic structure may fulfill multiple functions at the same time. Firstly, the thermoplastic structure may act as a mask during a (for instance tin) plating process to achieve an exposed pad as a component assembly section being free of any corresponding plating material (for instance being tin-free). Simultaneously, the thermoplastic structure may function as protection layer to prevent copper oxidation and other undesired phenomena.

For instance, a hot melt adhesive-type thermoplastic structure may be applied in a simple way by a hot melt dispensing machine.

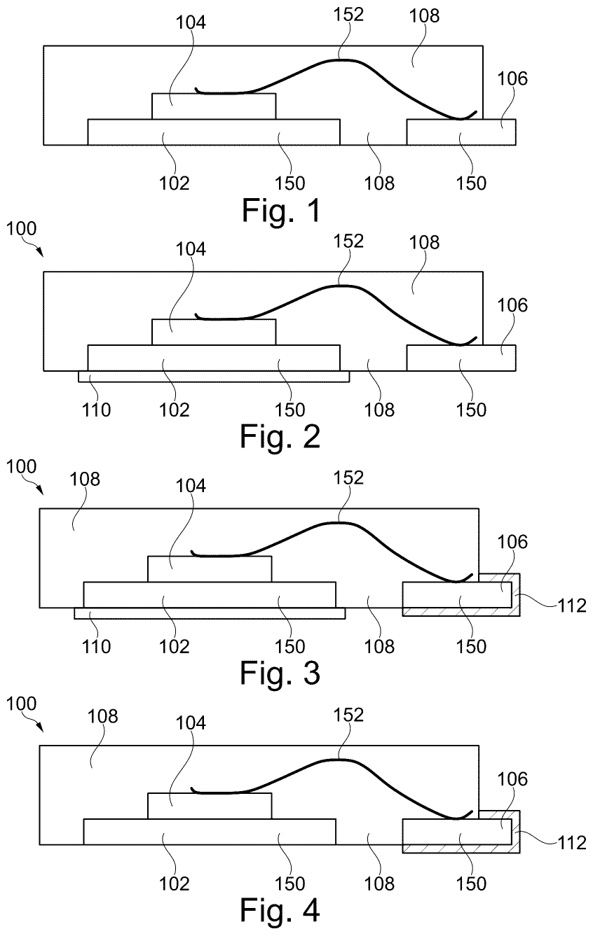

FIG. 1 to FIG. 5 show cross-sectional views of structures obtained during carrying out a method of manufacturing a package 100, shown in FIGS. 3-5, according to an exemplary embodiment.

Referring to FIG. 1, starting point of the manufacturing process may be a carrier 150, which may be embodied as a leadframe structure. For example, the carrier 150 may be a patterned and optionally bent metal plate, for instance made of copper. The carrier 150 comprises a component assembly section 102, which may be embodied as a die pad, and which may be electrically conductive. Moreover, the carrier 150 may comprise a lead section 106 comprising a plurality of electrically conductive leads. One or more lead sections 106 may be provided separately from the component assembly section 102 or may be integrally formed with the component assembly section 102.

An electronic component 104 may be mounted on the component assembly section 102. The electronic component 104 may be a semiconductor chip, for instance a power semiconductor chip. For instance, at least one terminal of the electronic component 104 may be connected on the component assembly section 102 in an electrically conductive way, for instance by soldering, sintering or electrically conductive glue. It is also possible that at least one terminal of the electronic component 104 is connected with the lead section 106 by an electrically conductive connection element 152. In the shown embodiment, the electrically conductive connection element 152 may be a bond wire or a bond ribbon. However, it is also possible, additionally or alternatively, to use a clip as electrically conductive connection element 152. Thus, the lead section 106 may be electrically coupled with the electronic component 104 and/or with the component assembly section 102. Although only one electronic component 104 is mounted on the component assembly section 102 according to FIG. 1, it is also possible that the package 100 comprises two or more electronic components 104.

Thereafter, an encapsulation process may be carried out for forming an encapsulant 108, for instance a mold compound. The encapsulant 108 may fully encapsulate the electronic component 104 and may only partially encapsulate the component assembly section 102 and the lead section 106. As a result, non-encapsulated parts of the component assembly section 102 and of the lead section 106 are exposed beyond the encapsulant 108.

Before forming a thermoplastic structure 110 as will be described referring to FIG. 2, the structure shown in FIG. 1 may be subjected to a surface oxide removal process for removing a surface oxide in particular from said exposed area of the component assembly section 102 exposed beyond the encapsulant 108. It may also be possible to remove a surface oxide from an exposed area of the lead section 106. Removing a surface oxide, such as copper oxide, from the exposed surface of the component assembly section 102 may decrease the thermal resistance of the component assembly section 102. This may improve the thermal performance, i.e. a heat dissipation capability, of the component assembly section 102 during operation of the readily manufactured package 100. During package operation, the electronic component 104 may generate a considerable amount of heat, which may be dissipated via the component assembly section 102 towards a heat sink 118, compare FIG. 5. Oxide removal may be accomplished for example by a surface treatment of the component assembly section 102, for instance a copper descaling process.

Referring to FIG. 2, the aforementioned thermoplastic structure 110 is formed as a plating mask to selectively cover the exposed area of the component assembly section 102 without covering the exposed area of the lead section 106. The thermoplastic structure 110 may thus be applied selectively only to the exposed surface of the component assembly section 102, and optionally to a connected surface portion of the encapsulant 108. More specifically, the thermoplastic structure 110 may be formed by dispensing flowable thermoplastic material using a dispensing machine (not shown) directly onto the component assembly section 102 and optionally onto connected surface portions of the encapsulant 108. Preferably, the thermoplastic structure 110 may be formed based on hot melt adhesive which may be heated and thereby rendered liquid or flowable. In this heated state, the dispensing machine may apply the flowable hot melt adhesive to desired surface portions of the preform of the package shown in FIG. 1. Subsequently to the application, said flowable thermoplastic material may be re-solidified by a temperature reduction (which may be active or passive) to thereby obtain the thermoplastic structure 110. It is also possible that the solidifying of the thermoplastic structure 110 occurs without taking active measures, due to an automatic cooling process. In particular, no curing process is necessary for creating the solid thermoplastic structure 110 on the component assembly section 102.

As a result, a thin film of thermoplastic structure 110 covers or coats selectively the component assembly section 102. The layer-type thermoplastic structure 110 covering selectively the exposed surface area of the component assembly section 102 functions as a plating-resistant coating protecting the component assembly section 102 simultaneously against undesired oxidation, etc. As a result of the described manufacturing process, the package 100 illustrated in FIG. 2 can be obtained.

Referring to FIG. 3, the structure obtained according to FIG. 2 may then be subjected to a metal plating process, for instance executed by sputtering or electroless deposition. Said plating process may selectively plate the exposed area of the lead section 106 with a metallic plating structure 112 while the thermoplastic structure 110 protects the component assembly section 102 against metallic plating. Thus, the component assembly section 102 may remain non-plated. The metallic plating structure 112 which is selectively formed on the exposed surface portions of the lead section 106 may for example comprise tin.

As already mentioned, package 100 comprises the component assembly section 102, the electronic component 104 being assembled with the component assembly section 102, and the lead section 106 being electrically coupled with the electronic component 104 and/or the component assembly section 102. The encapsulant 108 fully encapsulates the electronic component 104 and partially encapsulates the component assembly section 102 and the lead section 106. A part of the component assembly section 102 and a part of the lead section 106 are exposed beyond the encapsulant 108. The thermoplastic structure 110 covers an exposed area of the component assembly section 102 without covering an exposed area of the lead section 106.

The thermoplastic structure 110 may be made of a material being reversibly deformable, for example being bringable in a flowable state, by heating. Advantageously, the thermoplastic structure 110 may be made of a plating resistant material being resistant to tin plating. Preferably, the thermoplastic structure 110 may be made of a material being temperature resistant at least up to 150° C. or even at least up to 170° C. This may ensure that the thermoplastic structure 110 reliably withstands a thermal annealing process of the package 100 without the risk of damage or deterioration. In a preferred embodiment, the thermoplastic structure 110 comprises a hot melt adhesive (HMA). Preferably, the thermoplastic structure 110 can be applied as a continuous layer on the component assembly section 102 so as to ensure a full coverage and thus full protection against plating and oxidation.

As shown in FIG. 3 as well, the exposed area of the lead section 106 is plated with a metallic plating structure 112 of a plating material such as tin. In contrast to this, the exposed area of the component assembly section 102 is not plated with said plating material thanks to the plating-resistance of the thermoplastic structure 110 covering the component assembly section 102 during a plating process.

Referring to FIG. 4, the manufacturing method may also comprise removing the thermoplastic structure 110 after the plating to thereby expose the component assembly section 102. Advantageously, the thermoplastic structure 110 may be configured for being removed from the exposed area of the component assembly section 102 by peeling off the tape-like thermoplastic structure 110. Thus, the thermoplastic structure 110 may be removed from the package 100 by peeling it off by hand or by a machine.

After removal of the thermoplastic structure 110, the bottom surface of the component assembly section 102 is exposed to an environment, which may simplify heat dissipation during operation of the package 100. The thermoplastic structure 110 may be peeled off from the package 100 directly before use, so that no or no noteworthy oxidation occurs on the non-plated component assembly section 102, for instance made of copper.

Referring to FIG. 5, a heat sink 118 may be mounted on the exposed component assembly section 102. For instance, such a heat sink 118 may comprise a metallic plate 154 to be attached to the exposed main surface of the component mounting area 104 with a plurality of cooling fins 156 extending from said metallic plate 154. For example, the heat sink 118 may be connected with the component assembly section 102 by a solder structure 116 or using a thermal interface structure (TIM, not shown in FIG. 5). Since the component assembly section 102 has not been plated when forming plating structure 112 on lead section 106, the exposed surface of the component assembly section 102 is smooth so that the thermal resistance between component assembly section 102 and heat sink 118 is small. This may ensure an efficient heat dissipation. Removing an oxide on the exposed surface of the component assembly section 102 may also contribute to the small thermal resistance along the heat removal path.

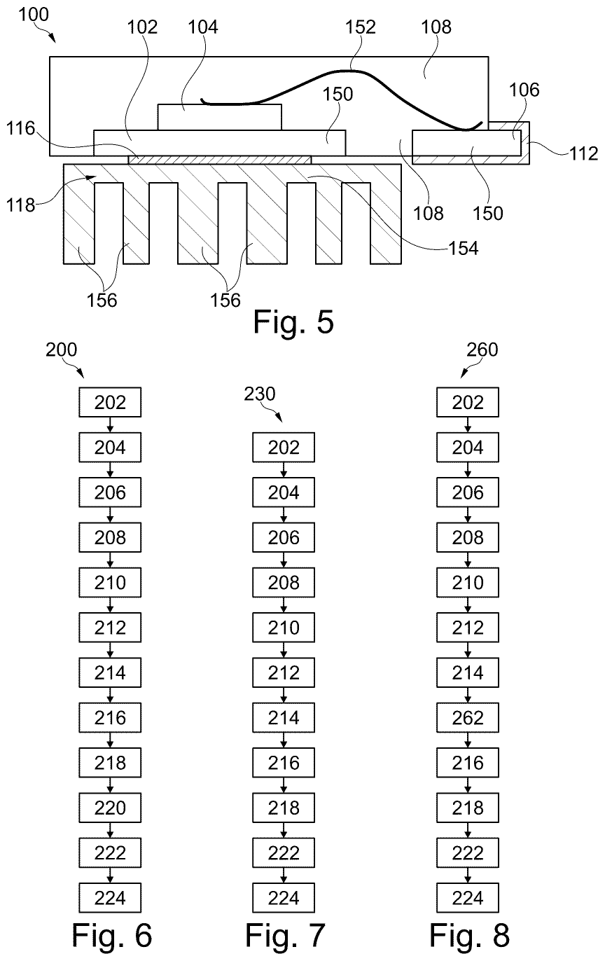

FIG. 6 illustrates a flowchart 200 of a method of manufacturing a package 100 according to an exemplary embodiment. The method according to flowchart 200 is based on a NiNiP-plated leadframe as component assembly section 102 and lead section 106.

In a block 202, electronic component 104 is assembled on component assembly section 102. This process may be denoted as die attach.

In a block 204, an electrically conductive connection element 152 is provided for connecting electronic component 104 with lead section 106. This process may be denoted as wire bonding.

In a block 206, a front of line auto vision inspection process may be executed.

In a block 208, a morphological adhesion promoter may be applied to the component assembly section 102, the lead section 106, the electronic component 104 and/or to the electrically conductive connection element 152 for improving adhesion with a subsequently applied encapsulant 108.

In a block 210, the electronic component 104, the component assembly section 102 and the lead section 106 may be at least partially encapsulated by an encapsulant 108. This process may be denoted as a molding process, followed by a post-mold curing process.

In a block 212, a reflow process may be executed (for instance twice).

In a block 214, a deflashing process may be executed.

In a block 216, a thermoplastic structure 110 may be applied selectively on an exposed area of the component assembly section 102. This process may be denoted as a hot melt adhesive masking process.

In a block 218, a metallic plating structure 112 may be applied selectively on the lead section 106. This process may be denoted as tin plating process.

In a block 220, the thermoplastic structure 110 may be removed, for instance may be peeled off from the component assembly section 102. This may be denoted as demasking.

In a block 222, the package 100 may be subjected to annealing.

In a block 224, a trim and form process may be executed.

FIG. 7 illustrates a flowchart 230 of a method of manufacturing a package 100 according to another exemplary embodiment. The method according to flowchart 230 is based on a NiNiP-plated leadframe as component assembly section 102 and lead section 106. Flowchart 230 differs from flowchart 200 in particular in that block 220 is omitted in FIG. 7. Thus, the thermoplastic structure 110 may remain on the component assembly section 102 according to FIG. 7. Thus, the thermoplastic mask remains as physical protection according to FIG. 7. The HMA mask acts as physical protection.

FIG. 8 illustrates a flowchart 260 of a method of manufacturing a package 100 according to still another exemplary embodiment. The method according to flowchart 260 is based on a copper leadframe as component assembly section 102 and lead section 106. Flowchart 260 differs from flowchart 230 in particular in that an additional block 262 is included in FIG. 8 between blocks 214 and 216. Block 262 relates to a copper descaling process executed to remove surface oxide prior to HMA masking. The copper leadframe package 100 manufactured according to FIG. 8 may benefit from a copper descaling process to remove surface oxide prior to HMA masking. According to FIG. 8, the thermoplastic structure 110 may form a mask which may remain as part of a readily manufactured package 100. The thermoplastic structure 110 may be removed by the user, for instance for obtaining access to the component assembly section 102, for instance for soldering.

Copper protection may be provided by the peelable mask. It may be possible to remove surface oxide prior to HMA masking. The HMA mask may protect oxidation.

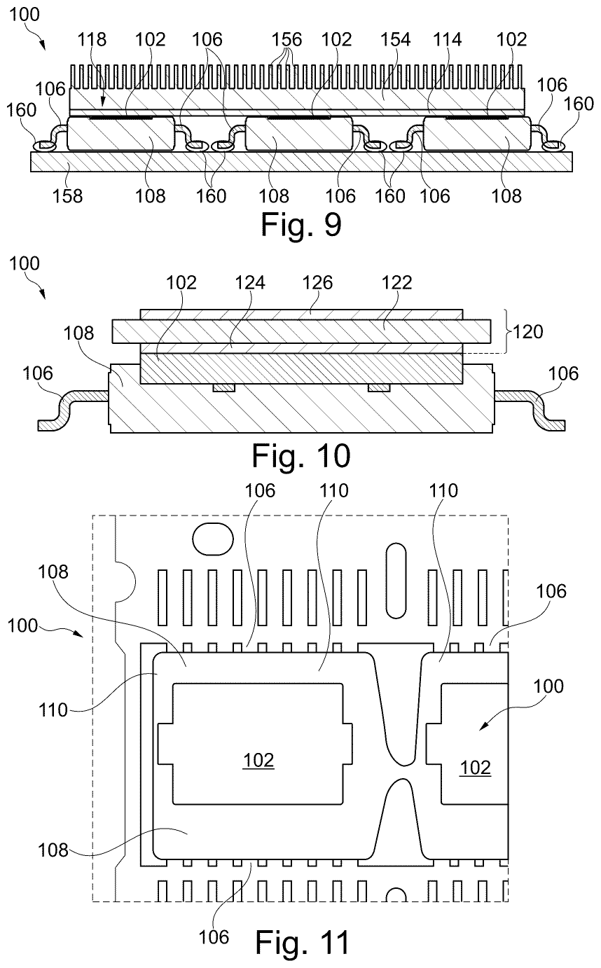

FIG. 9 illustrates a side view of a package 100 according to an exemplary embodiment.

In the embodiment of FIG. 9, a plurality of separate package bodies are provided, each comprising an electronic component 104 on a component assembly section 102 and connected with respective lead sections 106. Since the respective electronic component 104, component assembly section 102 and portions of the lead sections 106 are partially or entirely encapsulated by a respective encapsulant 108, not all of these constituents are visible in FIG. 9.

By a process similar to that described above referring to FIG. 1 to FIG. 5, exposed surface portions of the lead sections 106 are plated, whereas an exposed surface portion of the component assembly sections 102 is non-plated thanks to the temporary provision of a thermoplastic structure 110 (no longer visible in FIG. 9). Heat sink 118, which can be constructed in a similar way as described above referring to FIG. 5, is thermally coupled with the exposed surface areas of component assembly sections 102 by a thermal interface structure 114 made of a thermal interface material (TIM). Moreover, the lead sections 106 are electrically and mechanically connected with a mounting base 158 (for example a printed circuit board, PCB) by electrically conductive connection structures 160, for example solder structures.

Advantageously, the uniform heat sink surface of FIG. 9 may enhance thermal heat dissipation.

FIG. 10 illustrates a side view of a package 100 according to another exemplary embodiment.

Package 100 according to FIG. 10 may be formed on the basis of one of the encapsulated bodies shown in FIG. 9. Moreover, a decoupling structure 120 is mounted on the exposed component assembly section 102. In the shown embodiment, the decoupling structure 120 comprises a central thermally conductive and electrically insulating sheet 122 covered with a respective metallic layer 124, 126 on each of two opposing main surfaces thereof. Sheet 122 may for instance be made of a ceramic material, such as aluminum nitride or aluminum oxide. Sheet 122 provides electric isolation and thermal coupling. The metallic layer 124 is connected with the exposed component assembly section 102, for instance by soldering, sintering or electrically conductive glue. The other metallic layer 126 is exposed towards an exterior of the package 100 and can for instance form the basis of a solder connection with another constituent of an electronic device (for instance a heat sink or a PCB). For example, the metallic layers 124, 126 may be copper or aluminum foils or layers and may be optionally patterned. The decoupling structure 120 may thus be embodied as a Direct Copper Bonding (DCB) substrate.

Package 100 according to FIG. 10 may enable a DCB application for providing reliable electrical isolation and thermal coupling. Moreover, the DCB may prevent copper oxidation of the exposed component assembly section 102, such as a copper leadframe die pad.

FIG. 11 to FIG. 13 show plan views of structures obtained during carrying out a method of manufacturing a package 100 according to an exemplary embodiment. More specifically, FIG. 11 to FIG. 13 illustrate structures obtained during a batch manufacturing process of producing multiple packages 100 based on a common leadframe comprising a plurality of carriers 150 each having a component assembly section 102 and lead sections 106.

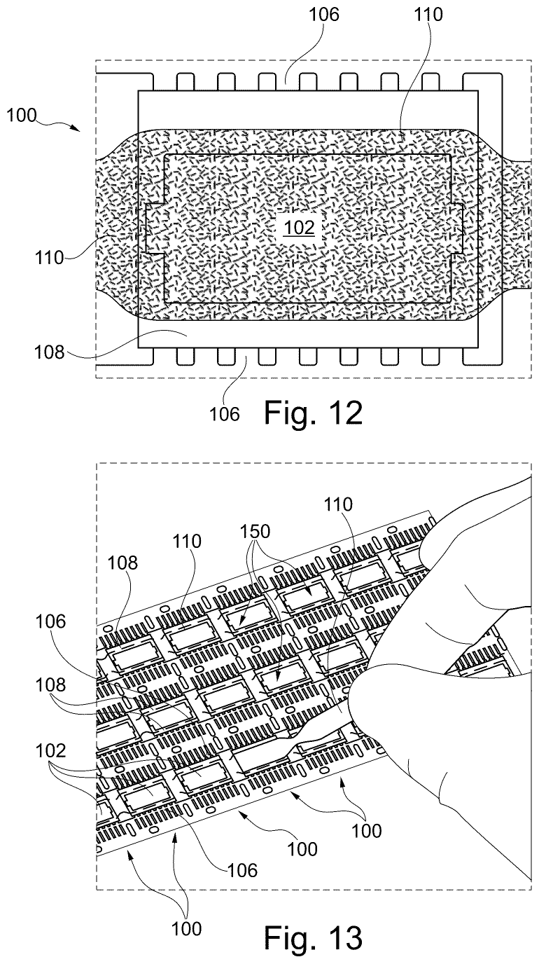

Referring to FIG. 11 and FIG. 12, a detailed view of a region around one package 100 is illustrated. As shown, a thermoplastic structure 110 may be formed as a common tape, strip or film being connected on and between adjacent packages 100.

Referring to FIG. 13, a plurality of still integrally connected packages 100 formed during batch manufacture are shown. As shown as well, an operator presently peels off by hand a common tape, strip or film of the thermoplastic structure 100 formed together for a row of packages 100.

In particular at a low plating speed of for example 3.5 minutes (corresponding to a sufficiently long chemical dipping time), the HMA mask may allow to achieve 100% tin free heat sink units.

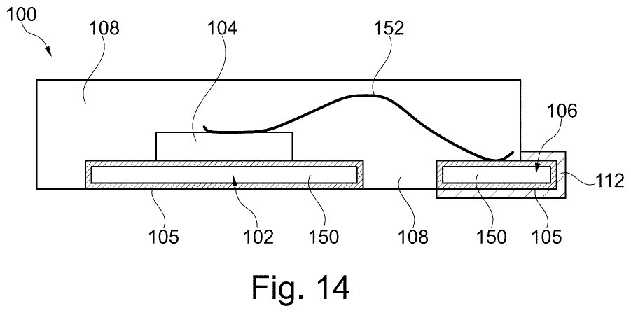

FIG. 14 shows a cross-sectional view of a package 100 according to another exemplary embodiment.

The package 100 according to FIG. 14 differs from the package 100 according to FIG. 4 in particular in that, according to FIG. 14, the component assembly section 102 is plated with a first metallic plating structure 105 of a first plating material. The lead section 106 is plated with the first metallic plating structure 105 of the first plating material and is additionally plated by a second metallic plating structure 112 of a second plating material plating an exposed area of the lead section 106 on top of the first metallic plating structure 105 of the first plating material. In contrast to this, the exposed area of the component assembly section 102 is not plated with said second plating material. This may be the result of the provision of a thermoplastic structure 110 being temporarily applied on the exposed surface of the component assembly section 102 (not shown in FIG. 14). More specifically, the first plating material may comprise for example NiNiP, and the second plating material may comprise for instance tin.

More precisely, the entire surface of the component assembly section 102 may be covered by the first metallic plating structure 105. Moreover, the entire surface of the lead section 106 may be covered by the first metallic plating structure 105. The encapsulated surface of the lead section 106 may be covered by the first metallic plating structure 105 only. In contrast to this, the non-encapsulated exposed surface of the lead section 106 may be covered by the first metallic plating structure 105 being covered, in turn, by the second metallic plating structure 112.

In the embodiment of FIG. 14, the component assembly section 102 and the lead section 106 are made of a plated metal body with a NiNiP plating. More specifically, the component assembly section 102 and the lead section 106 may be formed based on a carrier 150 which can be a copper leadframe pre-fabricated with a NiNiP plating. During the manufacturing process of package 100 according to FIG. 14, which can be as described above referring to FIG. 1 to FIG. 4 with the exception of the use of a different carrier 150, an additional tin plating is formed on part of the NiNiP plating of lead section 106, while such an additional tin plating does not occur on the NiNiP plating of the component assembly section 102 since the latter is covered during the additional plating process by the plating-resistant thermoplastic structure 110.

After completion of the second plating process, the thermoplastic structure 110 may be peeled off or stripped off leaving the illustrated package 100 behind.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a component assembly section;
at least one electronic component being assembled with the component assembly section;
at least one lead section being electrically coupled with the at least one electronic component and/or with the component assembly section;
an encapsulant at least partially encapsulating the at least one electronic component and partially encapsulating the component assembly section and the at least one lead section so that part of the component assembly section and part of the at least one lead section are exposed beyond the encapsulant; and
a thermoplastic structure covering an exposed area of the component assembly section without covering an exposed area of the at least one lead section.

2. A package, comprising:
a component assembly section plated with a first metallic plating structure of a first plating material;
at least one electronic component being assembled with the component assembly section;
at least one lead section plated with the first metallic plating structure of the first plating material and being electrically coupled with the at least one electronic component and/or with the component assembly section;
an encapsulant at least partially encapsulating the at least one electronic component and partially encapsulating the component assembly section and the at least one lead section so that part of the component assembly section and part of the at least one lead section are exposed beyond the encapsulant; and
a second metallic plating structure of a second plating material plating an exposed area of the at least one lead section on top of the first metallic plating structure of the first plating material, wherein an exposed area of the component assembly section is not plated with said second plating material.

3. The package according to claim 1, wherein the thermoplastic structure is made of a material being reversibly deformable, for example being bringable in a flowable state, by heating.

4. The package according to claim 1, comprising at least one of the following features:
wherein the exposed area of the at least one lead section is plated with a metallic plating structure of a plating material, and the exposed area of the component assembly section is not plated with said plating material;
wherein the thermoplastic structure is made of a plating resistant material, for example a tin plating resistant material.

5. The package according to claim 1, wherein the thermoplastic structure is made of a material being temperature resistant, for example at least up to 140° C.

6. The package according to claim 1, wherein the thermoplastic structure comprises an adhesive, for example a hot melt adhesive.

7. The package according to claim 1, wherein the thermoplastic structure is a continuous layer.

8. The package according to claim 1, wherein the thermoplastic structure is configured for being removed from the exposed area of the component assembly section by peeling off the thermoplastic structure.

9. The package according to claim 1, comprising a metallic plating structure covering the exposed area of the at least one lead section.

10. The package according to claim 1, wherein the component assembly section comprises a die pad and/or a clip.

11. The package according to claim 1, comprising at least one of the following features:
wherein the component assembly section and/or the at least one lead section forms or form part of a structured and/or bent metallic plate, for instance of a leadframe structure;
wherein the component assembly section is made of a non-plated metal body, for example is made of copper;
wherein the component assembly section is made of a plated metal body, for example is made of a metal body with a NiNiP plating.

12. The package according to claim 2, comprising at least one of the following features:
wherein the first plating material comprises NiNiP;
wherein the second plating material comprises tin.

13. A method of manufacturing a package, the method comprising:
assembling at least one electronic component with a component assembly section;
electrically coupling at least one lead section with the at least one electronic component and/or with the component assembly section;
at least partially encapsulating the at least one electronic component and partially encapsulating the component assembly section and the at least one lead section with an encapsulant so that part of the component assembly section and part of the at least one lead section are exposed beyond the encapsulant; and
forming a thermoplastic structure covering an exposed area of the component assembly section without covering an exposed area of the at least one lead section.

14. The method according to claim 13, wherein the method comprises removing the thermoplastic structure to thereby expose the component assembly section.

15. The method according to claim 14, wherein the method comprises mounting a heat sink on the exposed component assembly section, for example by a solder structure or using a thermal interface structure.

16. The method according to claim 14, wherein the method comprises mounting a decoupling structure on the exposed component assembly section, for example a decoupling structure comprising a central thermally conductive and electrically insulating sheet covered with a respective metallic layer on each of two opposing main surfaces thereof so that one of said metallic layers is connected with the exposed component assembly section and the other one of said metallic layers is exposed towards an exterior.

17. The method according to claim 13, wherein the method comprises plating the exposed area of the at least one lead section with a metallic plating structure while the thermoplastic structure protects the component assembly section against metallic plating.

18. The method according to claim 14, wherein the method comprises removing the thermoplastic structure after said plating.

19. The method according to claim 13, wherein the method comprises, before forming the thermoplastic structure, removing surface oxide at least from said exposed area of the component assembly section exposed beyond the encapsulant.

20. The method according to claim 13, wherein the method comprises forming the thermoplastic structure by dispensing flowable thermoplastic structure material using a dispensing machine, and subsequently solidifying said thermoplastic structure material by a temperature reduction to thereby obtain the thermoplastic structure.
